(19) United States
(12) Patent Application Publication
(10) Pub. No.: US 2023/0062333 A1
(43) Pub. Date: Mar. 2, 2023

(54) SEMICONDUCTOR DEVICE AND SUBSTRATE

(71) Applicant: Kioxia Corporation, Tokyo (JP)

(72) Inventor: Tomonori KAWASAKI, Yokkaichi (JP)

(73) Assignee: Kioxia Corporation, Tokyo (JP)

(21) Appl. No.: 17/687,093

(22) Filed: Mar. 4, 2022

(30) Foreign Application Priority Data
Aug. 31, 2021 (JP) 2021-141525

(51) Int. Cl. H01L 23/00; H01L 25/18; H01L 25/065; H01L 25/00

(52) U.S. Cl. CPC H01L 24/05; H01L 25/18; H01L 25/0657; H01L 25/50; H01L 24/08; H01L 2224/08145; H01L 27/11582

(57) ABSTRACT

A semiconductor device includes a first layer including a plurality of first pads, and a second layer including a plurality of second pads. The plurality of first pads are bonded to the plurality of second pads, respectively. At least one of the first pads or the second pads continuously surrounds an insulating portion.

### CROSS-REFERENCE TO RELATED APPLICATION(S)

This application is based upon and claims the benefit of priority from Japanese Patent Application No. 2021-141525, filed Aug. 31, 2021, the entire contents of which are incorporated herein by reference.

### FIELD

Embodiments described herein relate generally to a semiconductor device and a substrate.

### BACKGROUND

In general, a semiconductor device may include a plurality of wafers bonded together.

### DESCRIPTION OF THE DRAWINGS

FIG. 1 is a cross-sectional view showing a configuration of a semiconductor device according to an embodiment.

FIG. 2 is a cross-sectional view showing the vicinity of a memory pillar of a memory cell array according to the embodiment.

FIG. 3 is a cross-sectional view showing a plurality of bonding pads according to the embodiment.

FIG. 4 shows views of the bonding pad according to the embodiment.

FIG. 5 shows cross-sectional views of states of the pbonding pad of a first stacked body and the bonding pad of a second stacked body at a time of bonding the first stacked body and the second stacked body according to the embodiment.

FIG. 6 shows cross-sectional views of a method of manufacturing a semiconductor device according to the embodiment.

FIG. 7 shows cross-sectional views of the method of manufacturing a semiconductor device according to the embodiment.

FIG. 8 shows cross-sectional views of the method of manufacturing a semiconductor device according to the embodiment.

FIG. 9 shows cross-sectional views of the method of manufacturing a semiconductor device according to the embodiment.

FIG. 10 is a cross-sectional view showing a semiconductor device of a first modification of the embodiment.

FIG. 11 is a cross-sectional view showing a semiconductor device of a second modification of the embodiment.

FIG. 12 is a cross-sectional view showing a shape of a bonding pad of a first example of the embodiment.

FIG. 13 is a cross-sectional view showing a shape of a bonding pad of a second example of the embodiment.

FIG. 14 is a cross-sectional view showing a shape of a bonding pad of a third example of the embodiment.

FIG. 15 is a cross-sectional view showing a shape of a bonding pad of a fourth example according to the embodiment.

FIG. 16 is a cross-sectional view showing a shape of a bonding pad of a fifth example of the embodiment.

### DETAILED DESCRIPTION

Embodiments provide a semiconductor device and a substrate capable of improving electrical characteristics.

In general, according to one embodiment, a semiconductor device includes a first layer including a plurality of first pads, and a second layer including a plurality of second pads. The plurality of first pads are bonded to the plurality of second pads, respectively. At least one of the first pads or the second pads continuously surrounds an insulating portion.

A substrate according to the embodiment includes a plurality of pads and one or more insulating portions made of an insulator. In the substrate according to the embodiment, in a plan view, at least one of the pads includes a region continuously disposed around the insulating portions.

Hereinafter, a semiconductor device according to an embodiment will be described with reference to the drawings. In the following description, configurations having the same or similar functions are denoted by the same reference numerals. Duplicate descriptions of those configurations may be omitted. A term “connection” is not limited to physical connection, and also includes electrical connection. That is, the term “connection” is not limited to a case of direct contact, and also includes a case where another member is interposed. A term “annular” is not limited to an annular shape, and also includes a rectangular annular shape. Terms “parallel”, “orthogonal”, and “identical” include cases of “substantially parallel”, “substantially orthogonal”, and “substantially identical”, respectively.

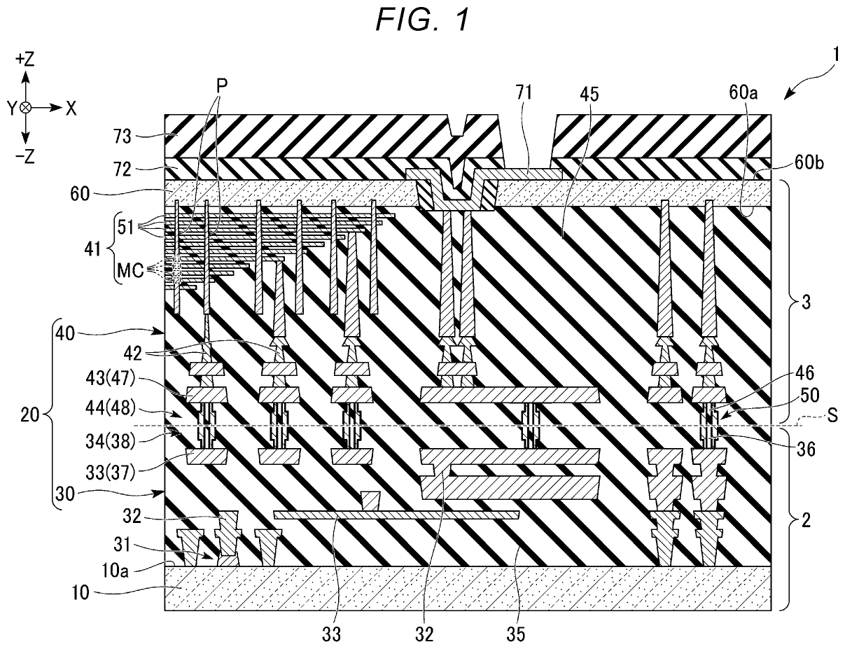

First, an X direction, a Y direction, a +Z direction, and a −Z direction are defined. The X direction and the Y direction are directions along a surface 10a of a first support substrate 10 (see FIG. 1) to be described later. The Y direction is a direction intersecting (for example, orthogonal to) the X direction. The +Z direction and the −Z direction are directions intersecting (for example, orthogonal to) the X direction and the Y direction, and are a thickness direction of the first support substrate 10. The +Z direction is a direction from the first support substrate 10 toward a second support substrate 60 (see FIG. 1). The −Z direction is a direction opposite to the +Z direction. When the +Z direction and the −Z direction are not distinguished from each other, the +Z direction and the −Z direction are simply referred to as a “Z direction”. In the following description, the “+Z direction” may be referred to as “upper” and the “−Z direction” may be referred to as “lower”. However, these expressions are for the sake of convenience, and do not define a direction of gravity. The Z direction is an example of a “first direction”. One of the X direction and the Y direction is an example of a “second direction”. The other of the X direction and the Y direction is an example of a “third direction”.

### (Embodiment)

<1. Overall Configuration of Semiconductor Device>

First, an overall configuration of a semiconductor device 1 according to an embodiment will be described. The semiconductor device 1 is a nonvolatile semiconductor memory device, and is, for example, a NAND flash memory.

FIG. 1 is a cross-sectional view showing a configuration of the semiconductor device 1. The semiconductor device 1 is, for example, a three-dimensional memory in which a circuit chip 2 and an array chip 3 are bonded to each other on a bonding surface S. The circuit chip 2 is an example of a “first layer”. The array chip 3 is an example of a “second layer”. The circuit chip 2 includes a control circuit (logic circuit) configured to control an operation of the array chip 3. Hereinafter, such a semiconductor device 1 will be described in detail.

The semiconductor device 1 includes, for example, the first support substrate 10, a stacked body 20, the second support substrate 60, and insulating layers 72 and 73.

The first support substrate 10 is a substrate provided in the circuit chip 2. The first support substrate 10 is, for example, a silicon substrate. The first support substrate 10 has the surface 10a on which the stacked body 20 is stacked. The first support substrate 10 is provided with a source region and a drain region of transistors 31 (described later) provided in the stacked body 20.

The stacked body 20 is positioned between the first support substrate 10 and the second layer 3 in the Z direction. More specifically, the stacked body 20 is positioned between the first support substrate 10 and the second support substrate 60 in the Z direction. The stacked body 20 includes a first stacked body 30 and a second stacked body 40. The first stacked body 30 is provided on the first support substrate 10. The first stacked body 30 is positioned between the first support substrate 10 and the second stacked body 40 in the Z direction. In the present embodiment, the circuit chip 2 is configured with the first support substrate 10 and the first stacked body 30. The first stacked body 30 includes a plurality of transistors 31 (only one is shown in FIG. 1), a plurality of contact plugs 32, a plurality of wirings 33, a plurality of pads 34, a first interlayer insulating film 35, and a plurality of first insulating portions 36. The first insulating portion 36 is an example of an “insulating portion”.

The transistors 31 are provided on the first support substrate 10. The transistors 31 are connected to the contact plugs 32. The transistors 31 are electrically connected to a memory cell array 41 or an external connection pad 71 via contact plugs 32 and 42, wirings 33 and 43, and pads 34 and 44 provided in the stacked body 20. The transistors 31 control, for example, the memory cell array 41.

The contact plugs 32, the wirings 33, and the pads 34 electrically connect the plurality of transistors 31 and the second stacked body 40. The contact plugs 32, the wirings 33, and the pads 34 are formed of a conductive material such as copper (Cu) or aluminum (Al). The contact plugs 32 extend in the Z direction and are wirings that electrically connect different layers in the first stacked body 30. The wirings 33 are wirings extending in the X direction or the Y direction.

The pads 34 are connection electrodes provided in the first stacked body 30. The pads 34 include an internal pad provided inside the first stacked body 30 and a bonding pad 38 exposed on the surface (bonding surface S) of the first stacked body 30. The bonding pad 38 is an example of the “pad”. A wiring 37 connected to the bonding pad 38 among the plurality of wirings 33 is an example of a “first wiring”. The bonding pad 38 will be described in detail later.

The first interlayer insulating film 35 is provided between the plurality of contact plugs 32, the plurality of wirings 33, and the plurality of pads 34, and electrically insulates these elements from each other. The first interlayer insulating film 35 is formed of, for example, tetraethyl orthosilicate (Si(OC₂H₅)₄ (TEOS), silicon oxide (SiO₂), or silicon nitride (SiN).

The second stacked body 40 is provided on the first stacked body 30. The second stacked body 40 is positioned between the first stacked body 30 and the second support substrate 60 in the Z direction. In the present embodiment, the array chip 3 is configured with the second support substrate 60 and the second stacked body 40. The second stacked body 40 includes the memory cell array 41, the plurality of contact plugs 42, the plurality of wirings 43, the plurality of pads 44, a second interlayer insulating film 45, and a plurality of second insulating portions 46. The second insulating portion 46 is an example of the “insulating portion”. That is, in the semiconductor device 1, at least one of the circuit chip (first layer) 2 and the array chip (second layer) 3 includes one or more insulating portions made of an insulator.

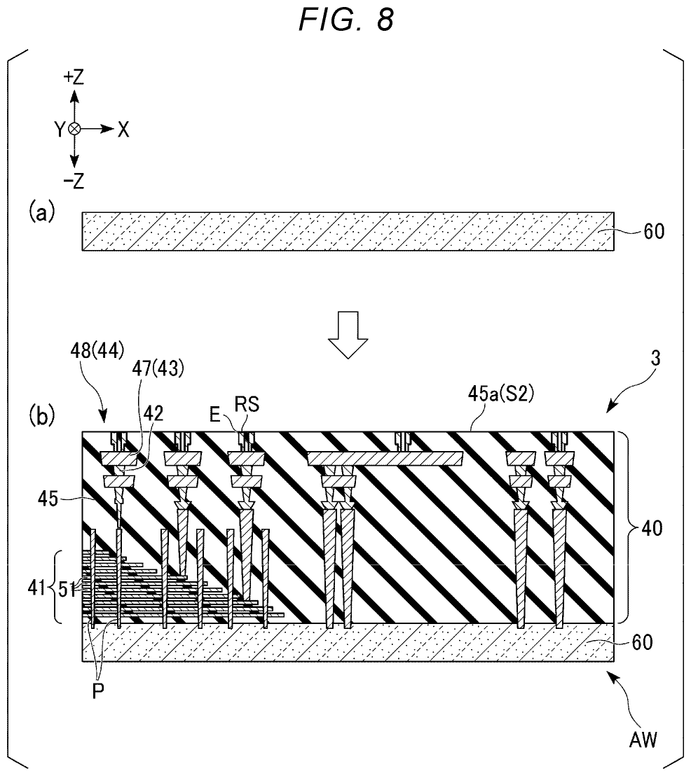

The memory cell array 41 is provided below the second support substrate 60. The memory cell array 41 is stacked on the second support substrate 60 during manufacture (see FIG. 8). The memory cell array 41 includes a plurality of conductive layers 51 and a plurality of memory pillars P. Each of the plurality of conductive layers 51 and the plurality of memory pillars P is connected to the contact plugs 42.

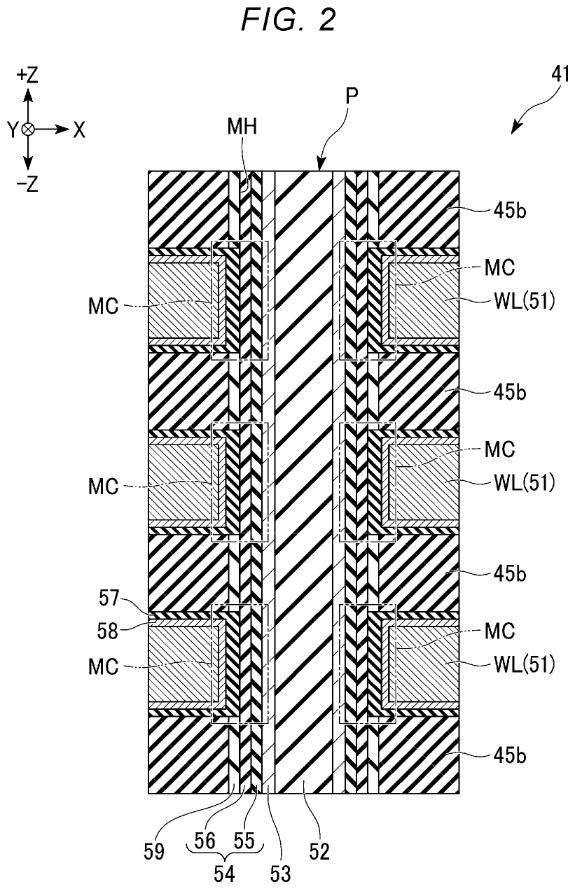

The plurality of conductive layers 51 are formed of, for example, tungsten (W) or polysilicon (Poly-Si) doped with impurities. The plurality of conductive layers 51 are stacked in the Z direction with interlayer insulating films 45b (see FIG. 2) provided in the second interlayer insulating film 45 interposed therebetween. One or two conductive layers 51 of the plurality of conductive layers 51 on a first stacked body 30 side (−Z direction side) function as a drain side select gate line SGD. One or two conductive layers 51 of the plurality of conductive layers 51 on a second support substrate 60 side (+Z direction side) function as a source side select gate line SGS. The remaining conductive layers 51 of the plurality of conductive layers 51 positioned between the drain side select gate line SGD and the source side select gate line SGS function as a plurality of word lines WLs.

The plurality of memory pillars P extend in the Z direction and penetrate the drain side select gate line SGD, the plurality of word lines WLs, and the source side select gate line SGS. Memory cells MCs are formed at intersection portions of the plurality of word lines WLs and the plurality of memory pillars P, respectively. As a result, the plurality of memory cells MCs are three-dimensionally arranged at intervals in the X direction, the Y direction, and the Z direction. The memory cells MCs will be described in detail later.

The contact plugs 42, the wirings 43, and the pads 44 electrically connect the memory cell array 41 or the external connection pad 71 to be described later to the first stacked body 30. The contact plugs 42, the wirings 43, and the pads 44 are formed of a conductive material such as copper or aluminum. The contact plugs 42 extend in the Z direction and are wirings that electrically connect different layers in the second stacked body 40. The wirings 43 are wirings extending in the X direction or the Y direction.

The pads 44 are connection electrodes provided in the second stacked body 40. The pads 44 include an internal pad provided inside the second stacked body 40 and a bonding pad 48 exposed on the surface (bonding surface S) of the second stacked body 40. In a state in which the first stacked body 30 and the second stacked body 40 are stacked, the bonding pad 48 of the second stacked body 40 is provided on the bonding pad 38 of the first stacked body 30, and is bonded to the bonding pad 38 of the first stacked body 30. That is, the semiconductor device 1 of the embodiment includes a bonding portion 50 to which the bonding pad 38 of the first layer (circuit chip) 2 and the bonding pad 48 of the second layer (array chip) 3 are bonded. The bonding pad 48 is an example of the “pad”. A wiring 47 connected to the bonding pad 48 among the plurality of wirings 43 is an example of a “second wiring”. The bonding pad 48 will be described in detail later.

The second interlayer insulating film 45 is provided among the plurality of contact plugs 42, the plurality of wirings 43, and the plurality of pads 44, and electrically insulates these elements from each other. The second interlayer insulating film 45 is formed of, for example, TEOS, silicon oxide, or silicon nitride.

The second support substrate 60 is provided above the second stacked body 40. The second support substrate 60 is positioned away from the first support substrate 10 in the Z direction. The second support substrate 60 is a substrate provided in the array chip 3 (second layer). The second support substrate 60 is, for example, a silicon substrate. A conductive region functioning as a source line of the memory cell array 41 is provided in the second support substrate 60. The second support substrate 60 has a first surface 60a facing the memory cell array 41 and a second surface 60b positioned on an opposite side of the first surface 60a. The external connection pad 71 is provided on the second surface 60b. The external connection pad 71 is provided with an external connection terminal (for example, a solder ball) (not shown), and is electrically connected to the outside of the semiconductor device 1 via the external connection terminal.

The insulating layer 72 is provided on the second support substrate 60. The insulating layer 73 is provided on the insulating layer 72. The insulating layers 72 and 73 are passivation films that protect the stacked body 20. The insulating layer 72 is, for example, a silicon oxide film. The insulating layer 73 is, for example, a polyimide film.

FIG. 2 is a cross-sectional view showing the vicinity of the memory pillar P of the memory cell array 41. As shown in FIG. 2, the plurality of word lines WLs are stacked in the Z direction with the interlayer insulating films 45b interposed therebetween. The plurality of word lines WLs extend in the X direction. The memory cell array 41 includes a memory hole MH in which the memory pillar P is provided. The memory pillar P extends in the Z direction inside the memory hole MH and penetrates the plurality of word lines WLs.

The memory pillar P has, for example, a circular shape or an elliptical shape when viewed from the Z direction. The memory pillar P includes, in order from the inside, a core insulator 52, a semiconductor body 53, and a memory film 54.

The core insulator 52 is a columnar body extending in the Z direction. The core insulator 52 includes, for example, silicon oxide. The core insulator 52 is located inside the semiconductor body 53.

The semiconductor body 53 extends in the Z direction and functions as a channel. The semiconductor body 53 is connected to the conductive region that functions as the source line of the second support substrate 60. The semiconductor body 53 covers an outer peripheral surface of the core insulator 52. The semiconductor body 53 includes, for example, silicon. The silicon is, for example, polysilicon formed by crystallizing amorphous silicon.

The memory film 54 extends in the Z direction. The memory film 54 covers an outer peripheral surface of the semiconductor body 53. The memory film 54 is positioned between an inner surface of the memory hole MH and an outer side surface of the semiconductor body 53. The memory film 54 includes, for example, a tunnel insulating film 55 and a charge storage film 56.

The tunnel insulating film 55 is positioned between the charge storage film 56 and the semiconductor body 53. The tunnel insulating film 55 includes, for example, silicon oxide, or silicon oxide and silicon nitride. The tunnel insulating film 55 is a potential barrier between the semiconductor body 53 and the charge storage film 56.

The charge storage film 56 is provided between each of the word line WLs and the interlayer insulating films 45b and the tunnel insulating film 55. The charge storage film 56 includes, for example, silicon nitride. An intersection portion of the charge storage film 56 and the word lines WLs functions as the memory cell MC. The memory cell MC holds data based on a presence or absence of charges in the intersection portion (charge storage portion) between the charge storage film 56 and the word lines WLs, or a stored charge amount. The charge storage portion is between the word lines WLs and the semiconductor body 53, and is surrounded by an insulating material.

A block insulating film 57 and a barrier film 58 may be provided between the word line WL and the interlayer insulating film 45b and between the word line WL and the memory film 54. The block insulating film 57 is an insulating film that prevents back tunneling. The back tunneling is a phenomenon in which the charges from the word lines WL to the memory film 54 return. The block insulating film 57 is, for example, a silicon oxide film, a metal oxide film, or a stacked structure film in which a plurality of insulating films are stacked. One example of a metal oxide is an aluminum oxide. The barrier film 58 is, for example, a titanium nitride film or a stacked structure film of titanium nitride and titanium.

A cover insulating film 59 may be provided between the interlayer insulating films 45b and the charge storage film 56. The cover insulating film 59 includes, for example, silicon oxide. The cover insulating film 59 protects the charge storage film 56 from etching at a time of processing. The cover insulating film 59 may be omitted, or may be partially left between the conductive layers 51 and the charge storage film 56 and used as the block insulating film.

<2. Configuration of Bonding Pads>

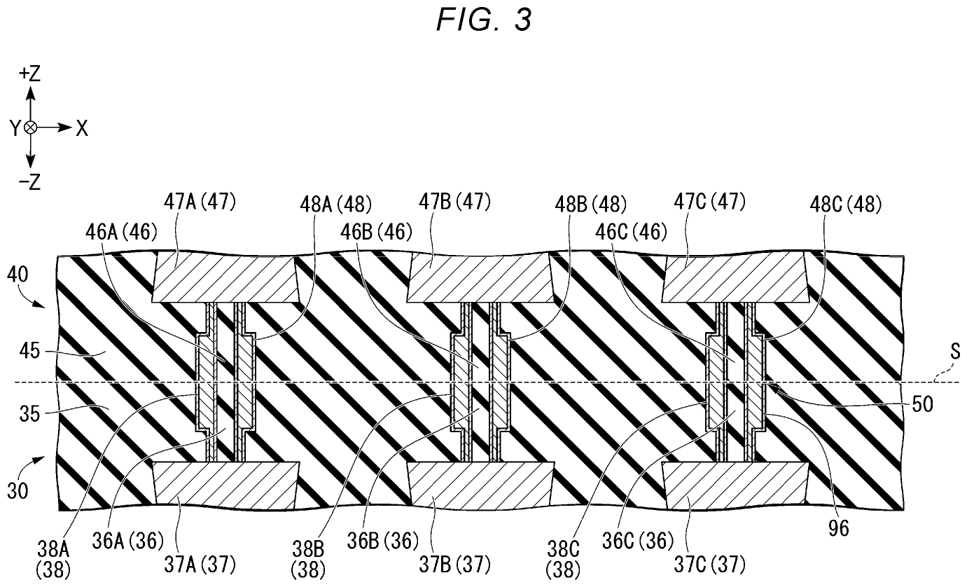

Next, configurations of the bonding pads 38 and 48 will be described. FIG. 3 shows cross-sectional views of the plurality of bonding pads 38 and 48. As shown in FIG. 3, the wiring 37 of the first stacked body 30 includes wirings 37A, 37B, and 37C electrically independent from each other. The first interlayer insulating film 35 is provided between the wirings 37A, 37B, and 37C in the X direction and the Y direction. Accordingly, the wirings 37A, 37B, and 37C are electrically insulated from each other. The wirings 37A, 37B, and 37C may have different potentials from each other. Hereinafter, when the wirings 37A, 37B, and 37C are not distinguished from each other, the wirings 37A, 37B, and 37C are referred to as the “wirings 37”.

The bonding pad 38 of the first stacked body 30 includes a bonding pad 38A connected to the wiring 37A, a bonding pad 38B connected to the wiring 37B, and a bonding pad 38C connected to the wiring 37C. The first interlayer insulating film 35 is provided between the bonding pads 38A, 38B, and 38C in the X direction and the Y direction. The bonding pads 38A, 38B, and 38C may have different potentials from each other. Hereinafter, when the bonding pads 38A, 38B, 38C are not distinguished from each other, the bonding pads 38A, 38B, 38C are referred to as the “bonding pads 38”.

The first insulating portions 36 of the first stacked body 30 include a first insulating portion 36A surrounded by the bonding pad 38A via a barrier metal layer 96 described later, a first insulating portion 36B surrounded by the bonding pad 38B via the barrier metal layer 96, and a first insulating portion 36C surrounded by the bonding pad 38C via the barrier metal layer 96. Hereinafter, when the first insulating portions 36A, 36B, and 36C are not distinguished from each other, the first insulating portions 36A, 36B, and 36C will be referred to as the “first insulating portions 36”. The first insulating portion 36 is formed of, for example, tetraethyl orthosilicate (Si(OC₂H₅)₄ (TEOS), silicon oxide (SiO₂) , or silicon nitride (SiN).

Similarly, the wiring 47 of the second stacked body 40 includes wirings 47A, 47B, and 47C electrically independent from each other. The second interlayer insulating film 45 is provided between the wirings 47A, 47B, and 47C in the X direction and the Y direction. Accordingly, the wirings 47A, 47B, and 47C are electrically insulated from each other. The wirings 47A, 47B, and 47C may have different potentials from each other. Hereinafter, when the wirings 47A, 47B, and 47C are not distinguished from each other, the wirings 47A, 47B, and 47C are referred to as the “wirings 47”.

The bonding pad 48 of the second stacked body 40 includes a bonding pad 48A connected to the wiring 47A, a bonding pad 48B connected to the wiring 47B, and a bonding pad 48C connected to the wiring 47C. The second interlayer insulating film 45 is provided between the bonding pads 48A, 48B, 48C in the X direction and the Y direction. The bonding pads 48A, 48B, 48C may have different potentials from each other. Hereinafter, when the bonding pads 48A, 48B, 48C are not distinguished from each other, the bonding pads 48A, 48B, 48C are referred to as the “bonding pads 48”.

The second insulating portions 46 of the second stacked body 40 include a second insulating portion 46A surrounded by the bonding pad 48A via the barrier metal layer 96, a second insulating portion 46B surrounded by the bonding pad 48B via the barrier metal layer 96, and a second insulating portion 46C surrounded by the bonding pad 48C via the barrier metal layer 96. Hereinafter, when the second insulating portions 46A, 46B, and 46C are not distinguished from each other, the second insulating portions 46A, 46B, and 46C are referred to as the “second insulating portions 46”. The second insulating portion 46 is formed of, for example, tetraethyl orthosilicate (Si(OC₂H₅)₄ (TEOS), silicon oxide (SiO₂), or silicon nitride (SiN).

The bonding pad 38 of the first stacked body 30 and the bonding pad 48 of the second stacked body 40 are bonded to each other on the bonding surface S. Accordingly, the bonding pad 38 of the first stacked body 30 and the bonding pad 48 of the second stacked body 40 are bonded to each other. That is, the semiconductor device 1 of the present embodiment includes the bonding portion 50 to which the bonding pad 38 of the circuit chip (first layer) 2 and the bonding pad 48 of the array chip (second layer) 3 are bonded. In the example shown in FIG. 3, the bonding pad 38 of the first stacked body 30 and the bonding pad 48 of the second stacked body 40 are provided in the same manner as each other. The expression “the same manner” means that the bonding pads 38 and 48 have the same three-dimensional shape. In this case, the bonding pad 38 of the first stacked body 30 and the bonding pad 48 of the second stacked body 40 are bonded to each other in a one-to-one correspondence relationship.

In the present embodiment, the bonding pad 38A of the first stacked body 30 and the bonding pad 48A of the second stacked body 40 are bonded to each other, so that the wiring 37A and the wiring 47A are electrically connected to each other. Similarly, the bonding pad 38B of the first stacked body 30 and the bonding pad 48B of the second stacked body 40 are bonded to each other, so that the wiring 37B and the wiring 47B are electrically connected to each other. The bonding pad 38C of the first stacked body 30 and the bonding pad 48C of the second stacked body 40 are bonded to each other, so that the wiring 37C and the wiring 47C are electrically connected to each other.

In the present embodiment, the bonding pads 38A, 38B, 38C, 48A, 48B, 48C have the same three-dimensional shape as each other. Therefore, in the following, one bonding pad 38 of the first stacked body 30 will be described in detail. The bonding pad 48 of the second stacked body 40 also has the same structure as the structure described below.

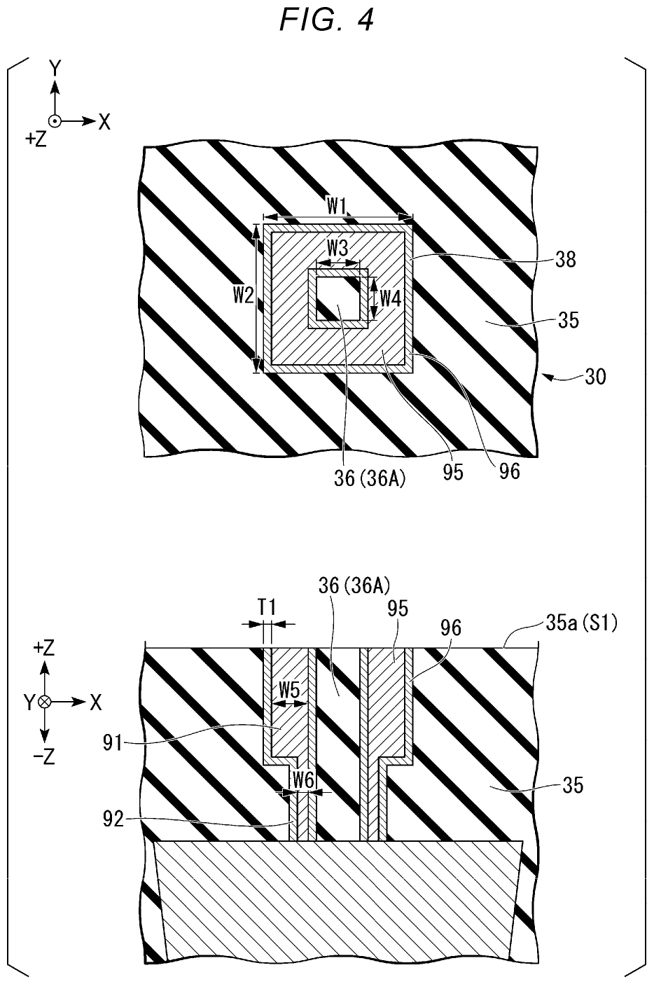

FIG. 4 shows views of the bonding pad 38. An upper view of FIG. 4 is a view showing the bonding pad 38 as viewed from the Z direction. That is, the upper view of FIG. 4 shows the bonding pad 38 on a plane perpendicular to a stacking direction when the stacking direction is a direction in which the circuit chip (first layer) 2 and the array chip (second layer) 3 are stacked. A lower view of FIG. 4 is an enlarged view of the bonding pad 38A of FIG. 3. In the present embodiment, an outer shape of the bonding pad 38 as viewed from the Z direction is a quadrilateral shape. Specifically, the outer shape of the bonding pad 38 is a square shape in which each of four sides extends in the X direction or the Y direction. In the plane perpendicular to the stacking direction, the bonding pad 38 includes a region continuously disposed around the first insulating portion 36. In the present embodiment, the first insulating portion 36 is disposed in an island shape at a center of the bonding pad 38. That is, when viewed from the Z direction, the first insulating portion 36 is not connected to the first interlayer insulating film 35, and the bonding pad 38 is disposed between the first insulating portion 36 and the first interlayer insulating film 35. In the present embodiment, a shape of the first insulating portion 36 as viewed from the Z direction is a quadrilateral shape (square shape). Specifically, the shape of the first insulating portion 36 viewed from the Z direction is a square shape in which each of the four sides extends in the X direction or the Y direction.

A width W1 of the bonding pad 38 in the X direction is not particularly limited, and is, for example, 300 nm to 5 pm. A width W2 of the bonding pad 38 in the Y direction is not particularly limited, and is, for example, 300 nm to 5 pm.

A width W3 of the first insulating portion 36 in the X direction is smaller than W1. A width W4 of the first insulating portion 36 in the Y direction is smaller than W2.

In the present embodiment, the bonding pad 38 includes a pad main body 91 and a wiring connection portion 92. The pad main body 91 is exposed to the bonding surface S (see FIG. 3) and is bonded to the bonding pad 48 of the second stacked body 40. The wiring connection portion 92 is positioned between the pad main body 91 and the wiring 37, and connects the pad main body 91 and the wiring 37. The wiring connection portion 92 is thinner than the pad main body 91. For example, a width W6 of the wiring connection portion 92 in the X direction is smaller than a width W5 of the pad main body 91 in the X direction. Similarly, a width of the wiring connection portion 92 in the Y direction is smaller than a width of the pad main body 91 in the Y direction. The pad main body 91 is connected to the wiring 37 via the corresponding wiring connection portion 92.

The bonding pad 38 includes a conductive portion 95 and the barrier metal layer 96. The conductive portion 95 forms a main portion of the bonding pad 38. The barrier metal layer 96 is provided between the conductive portion 95 and the first insulating portion 36 in the X direction and the Y direction. Similarly, the barrier metal layer 96 is provided between the conductive portion 95 and the first interlayer insulating film 35 in the X direction and the Y direction. Similarly, the barrier metal layer 96 is provided between the bonding pad 38 and the first interlayer insulating film 35. The barrier metal layer 96 is a metal layer that prevents diffusion of the conductive material (for example, copper or aluminum) provided in the conductive portion 95 into the first interlayer insulating film 35. Each of the conductive portion 95 and the barrier metal layer 96 is provided on both the pad main body 91 and the wiring connection portion 92. A film thickness T1 of the barrier metal layer 96 in the X direction is smaller than the width W5 of the conductive portion 95 of the pad main body 91 and the width W6 of the conductive portion 95 of the wiring connection portion 92. A film thickness of the barrier metal layer 96 in the Y direction is smaller than a width of the conductive portion 95 of the pad main body 91 in the Y direction and a width of the conductive portion 95 of the wiring connection portion 92 in the Y direction.

The bonding pad 38 of the first stacked body 30 has been described above. In the above description, the bonding pad 48 of the second stacked body 40 may read the “bonding pad 38” as the “bonding pad 48” and read the “wiring 37” as the “wiring 47”.

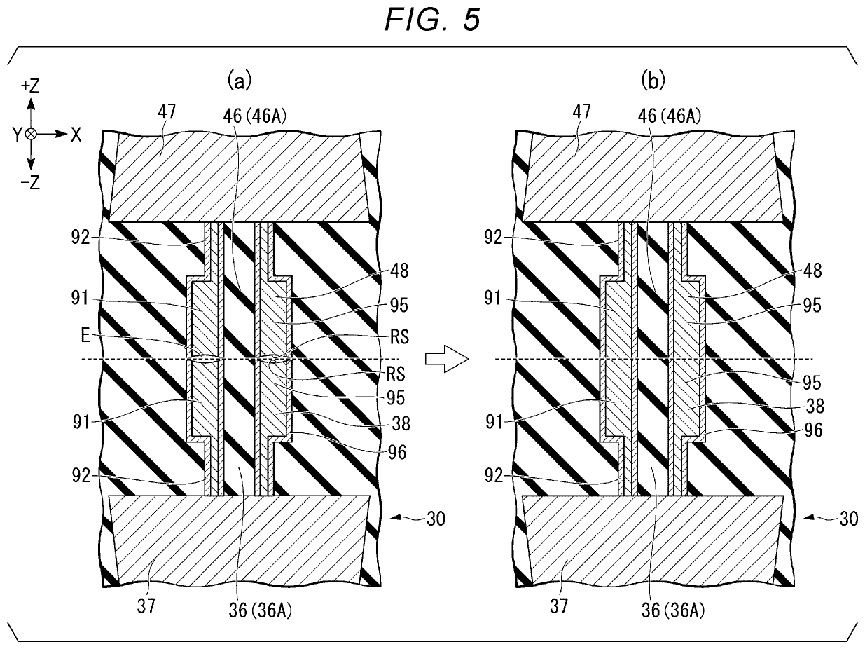

FIG. 5 shows cross-sectional views of states of the bonding pad 38 of the first stacked body 30 and the bonding pad 48 of the second stacked body 40 at a time of bonding the first stacked body 30 of the circuit chip 2 and the second stacked body 40 of the array chip 3. The circuit chip 2 before being bonded includes the plurality of bonding pads 38 and one or more first insulating portions 36 made of an insulator in a plan view, and the bonding pad 38 is a substrate including the region continuously disposed around the first insulating portion 36. The array chip 3 before being bonded includes the plurality of bonding pads 48 and one or more second insulating portions 46 made of an insulator in the plan view, and the bonding pad 48 is a substrate including the region continuously disposed around the second insulating portion 46. An end portion E of the bonding pad 38 has a recessed portion RS recessed in a bowl shape in the −Z direction. Since a size of the conductive portion 95 in the X direction and the Y direction is small in the first insulating portion 36, the recessed portion RS of the bonding pad 38 is shallower than a case where the first insulating portion 36 is not provided. The end portion E of the bonding pad 48 has the recessed portion RS recessed in the bowl shape in the +Z direction. Since the size of the conductive portion 95 in the X direction and the Y direction is small in the second insulating portion 46, the recessed portion RS of the bonding pad 48 is shallower than a case where the second insulating portion 46 is not provided.

When the first stacked body 30 and the second stacked body 40 are bonded to each other, the first stacked body 30 and the second stacked body 40 are heated. As a result, the recessed portion RS of the bonding pad 38 and the recessed portion RS of the bonding pad 48 are filled and disappear (or reduced).

<3. Method of Manufacturing Semiconductor Device>

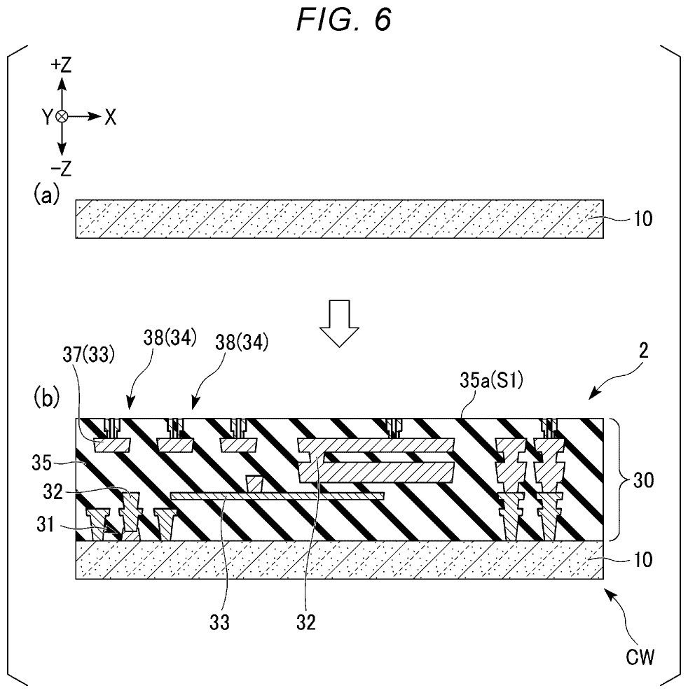

Next, a method of manufacturing the semiconductor device 1 will be described. FIGS. 6 to 9 are cross-sectional views showing the method of manufacturing the semiconductor device 1.

FIG. 6 shows manufacturing stages of the circuit chip 2. The circuit chip 2 is manufactured as a part of a circuit wafer CW. The circuit wafer CW includes the plurality of circuit chips 2. The circuit wafer CW is obtained by forming the first stacked body 30 on the first support substrate 10. The first stacked body 30 includes the transistors 31, the contact plugs 32, the wirings 33, the pads 34, and the first interlayer insulating film 35. These members are formed for each layer. The circuit wafer CW is formed by repeating a film formation of each layer and a processing by photolithography or the like. As a film forming method and a processing method other than using the bonding pad 38, a known method may be used. The plurality of bonding pads 38 are exposed on a bonding surface S1 of the circuit wafer CW on a side opposite to the first support substrate 10. Accordingly, the circuit wafer CW is completed.

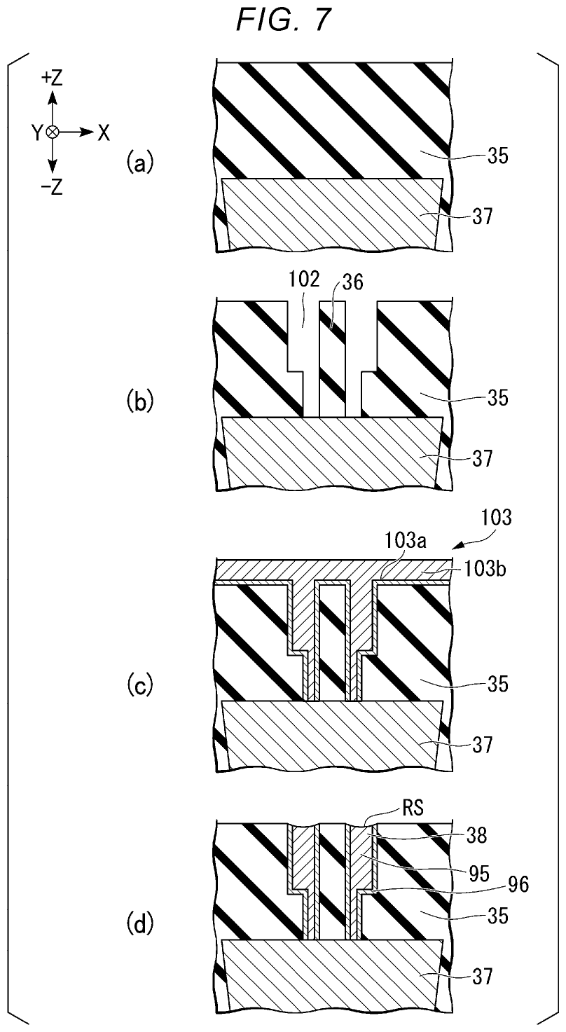

Here, a method of forming the bonding pad 38 will be described in detail. FIG. 7 shows details of manufacturing stages of the bonding pad 38. First, as shown in (a) in FIG. 7, a part of the first interlayer insulating film 35 is provided on the wiring 37. The first interlayer insulating film 35 provided on the wiring 37 is formed of, for example, silicon oxide (SiO₂).

Next, as shown in (b) in FIG. 7, a resist pattern is formed by a photo engraving process (PEP), and the first interlayer insulating film 35 is etched by reactive ion etching (RIE). Accordingly, a plurality of holes 102 and the plurality of first insulating portions 36 are formed at positions where the bonding pad 38 is provided in a subsequent step.

Next, as shown in (C) in FIG. 7, a conductive layer 103a, which is a source of the barrier metal layer, is formed on an inner surface of the hole 102 and around the first insulating portion 36. Thereafter, a conductive material (for example, a metal material such as copper or aluminum) is embedded in the hole 102 to form a conductive portion 103b which is a source of the pad main body 91. Accordingly, a conductive portion 103 filling the holes 102 is formed. The conductive portion 103 is a conductive portion serving as a source of the plurality of bonding pads 38.

Next, as shown in (D) in FIG. 7, the conductive portion 103 is flattened by chemical mechanical polisher (CMP). Accordingly, the plurality of bonding pads 38 are formed from the conductive portion 103. At this time, the recessed portion RS due to dishing is formed on a surface of an upper end portion of each bonding pad.

FIG. 8 shows manufacturing stages of the array chip 3. The array chip 3 is manufactured as a part of an array wafer AW. The array wafer AW includes a plurality of array chips 3. The array wafer AW shown in FIG. 8 is in a state before being bonded to the circuit wafer CW, and is vertically inverted with respect to the array chip 3 shown in FIG. 1.

The array wafer AW is obtained by forming the second stacked body 40 on the second support substrate 60. The second stacked body 40 includes the memory cell array 41, the contact plugs 42, the wirings 43, the pads 44, and the second interlayer insulating film 45. These members are formed for each layer. The array wafer AW is formed by repeating the film formation of each layer and the processing by photolithography or the like. As the film forming method and the processing method other than using the bonding pad 48, the known method can be used. The plurality of bonding pads 48 are exposed on a bonding surface S2 of the array wafer AW on a side opposite to the second support substrate 60. A method of forming the bonding pad 48 is, for example, the same as the method of forming the bonding pad 38 described with reference to FIG. 7. Accordingly, the circuit wafer CW is completed.

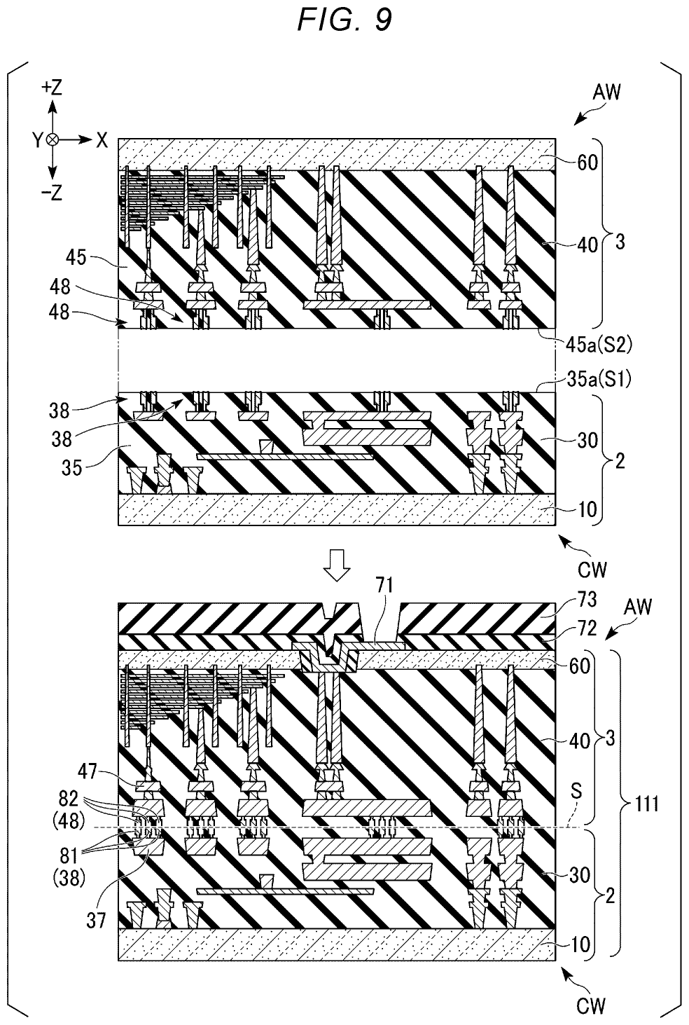

FIG. 9 shows bonding stages of the circuit wafer CW and the array wafer AW. Specifically, the circuit wafer CW and the array wafer AW are heated, the bonding surface S1 of the circuit wafer CW and the bonding surface S2 of the array wafer AW are faced to each other (that is, the bonding pads 38 of the first stacked body 30 and the bonding pads 48 of the second stacked body 40 are faced to each other), and the circuit wafer CW and the array wafer AW are bonded together. Accordingly, the first interlayer insulating film 35 and the second interlayer insulating film 45 are bonded to each other.

Next, the array wafer AW and the circuit wafer CW are annealed at 400° C. Accordingly, the bonding pads 38 and the bonding pads 48 are bonded to each other, and the bonding portion 50 is formed. Accordingly, a bonded body 111 in which the circuit wafer CW and the array wafer AW are bonded to each other is formed.

Next, the second support substrate 60 is thinned. A thickness of the second support substrate 60 is reduced by, for example, the CMP. Next, the external connection pad 71 and the insulating layers 72 and 73 are provided on the second support substrate 60 by the known method. Then, the bonded body 111 is cut along a dicing line (not shown). Accordingly, the bonded body 111 is divided into a plurality of chips (semiconductor devices 1). Accordingly, the semiconductor device 1 is obtained.

<4. Advantages>

For comparison, a case where there is no insulating portion in the bonding pad is considered. In such a configuration of a comparative example, when large dishing is generated at an end portion of the bonding pad due to the CMP or another reason, a space may remain between two bonding pads to be bonded. In this case, it is necessary to increase an annealing temperature in order to bond the two bonding pads. When the annealing temperature is increased, voids or the like may be formed. In addition, when the annealing temperature is increased so as to increase thermal expansion in order to more reliably bond the two bonding pads, a metal contained in the barrier metal layer may be diffused into the inside of the insulator, and barrier property of the barrier metal layer may be reduced.

On the other hand, in the present embodiment, the bonding pad 38 includes the region continuously disposed around the first insulating portion 36. Therefore, in the X direction and the Y direction, the width of the bonding pad 38 is smaller, the large dishing is less likely to occur, and a recess amount of the recessed portion RS is smaller. Therefore, a temperature at a time of annealing can be lowered, and the voids and the like are less likely to be generated. As a result, reliability and yield can be improved.

At the time of annealing, the barrier metal layer 96 prevents expansion of the conductive portion 95 and prevents the bonding pads from being bonded to each other. Therefore, it is preferable that a contact area between the barrier metal layer 96 and the conductive portion 95 is small. Since the bonding pad 38 of the present embodiment includes the region continuously disposed around the insulating portions 36 and 46, the contact area between the barrier metal layer 96 and the conductive portion 95 can be reduced. In addition, since a volume of the conductive portion 95 can be increased as compared with a case where the size of the conductive portion 95 is reduced, a volume increase amount of the conductive portion 95 at the time of annealing can be increased. Therefore, even when the annealing temperature is lowered, the bonding pad 38 and the bonding pad 48 can be bonded to each other. As a result, the reliability and the yield can be further improved.

<5. Modifications>

Hereinafter, the modifications will be described. Configurations other than those described below in the present modification are the same as those of the above embodiment.

<5.1 Modification 1>

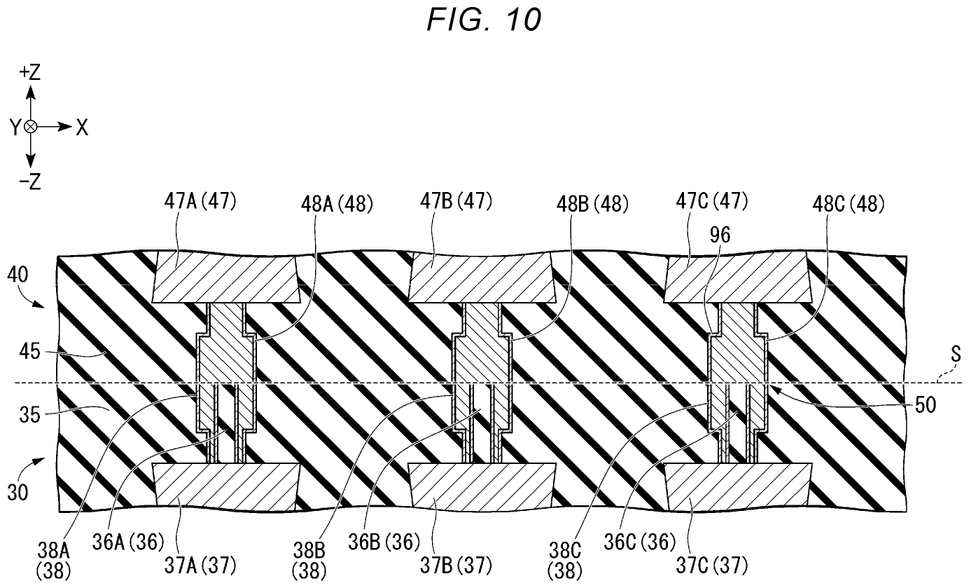

FIG. 10 is a cross-sectional view showing the semiconductor device 1 according to a first modification. In the present modification, the bonding pad 48 is the bonding pad in the related art in which the second insulating portion 46 is not provided at the center. In the semiconductor device 1 of the first modification, the at least one of the circuit chip (first layer) 2 and the array chip (second layer) 3 includes the one or more insulating portions 36 and 46 made of an insulator, and at least one of the bonding pads 38 and 48 includes the region continuously disposed around the insulating portions.

In the present modification, since the recess amount of the recessed portion RS of the bonding pad 38 of the first stacked body 30 is small, the bonding can be performed at a lower annealing temperature than in the case where the first insulating portion 36 is not provided. Therefore, it is possible to improve electrical characteristics of the semiconductor device 1.

<5.2 Modification 2>

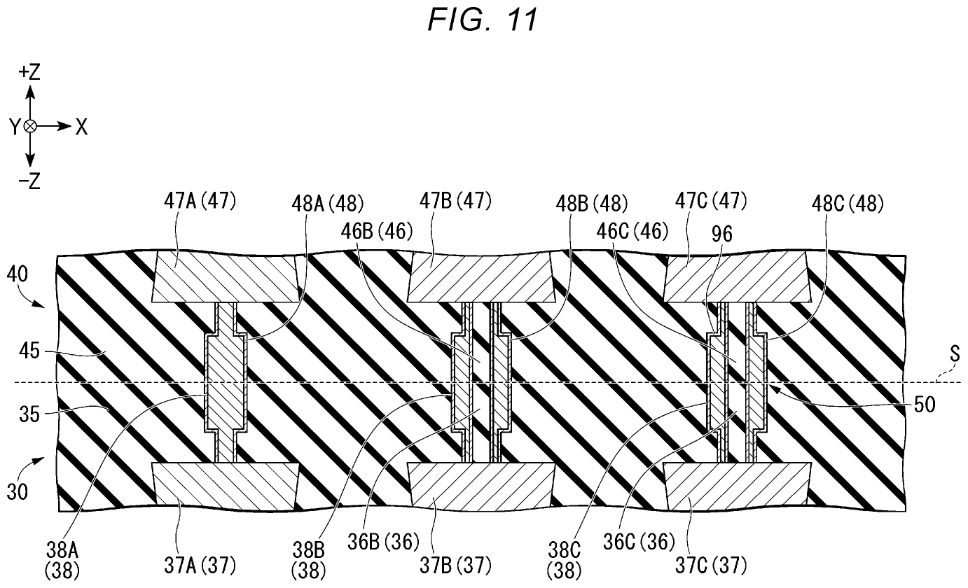

FIG. 11 is a cross-sectional view showing the semiconductor device 1 according to a second modification. In the present modification, the bonding pad 38A of the first stacked body 30 and the bonding pad 48A of the second stacked body 40 are the bonding pads in the related art in which the insulating portion 36 is not provided. In the semiconductor device 1 of the second modification, the at least one of the bonding pads 38 and 48 includes the region continuously disposed around the insulating portions. That is, in the semiconductor device 1 according to the second modification, both the circuit chip (first layer) 2 and the array chip (second layer) 3 include the one or more insulating portions 36 and 46 made of an insulator, and the at least one of the bonding pads 38 and 48 includes the region continuously disposed around the insulating portions.

In the present modification, since the recess amount of the recessed portion RS of the bonding pad 38 of the first stacked body 30 and the recess amount of the recessed portion RS of the bonding pad 48 of the second stacked body 40 are small, the bonding can be performed at the lower annealing temperature than in a case where the first insulating portion 36 and the second insulating portion 46 are not provided. Therefore, it is possible to improve the electrical characteristics of the semiconductor device 1. In addition, the bonding pad 38A and the bonding pad 48A having a small pad size can be bonded at a low annealing temperature since the recess amount of the recessed portion RS of the bonding pad is small. Therefore, it is possible to improve the electrical characteristics of the semiconductor device 1.

<6. Examples>

Hereinafter, some examples regarding shapes of the bonding pads 38 and 48 will be described. Hereinafter, the shape of the bonding pad 38 of the first stacked body 30 will be described as a representative. The same applies to the shape of the bonding pad 48 of the second stacked body 40. The shapes of the bonding pads 38 and 48 are not limited to contents of the examples described below.

<6.1 First Example>

FIG. 12 is a cross-sectional view showing the shape of the bonding pad 38 according to a first example. FIG. 12 shows the bonding pad 38 on the plane perpendicular to the stacking direction when the stacking direction is the direction in which the circuit chip (first layer) 2 and the array chip (second layer) 3 are stacked. In the first example, the outer shape of the bonding pad 38 viewed from the Z direction is the quadrilateral shape. Specifically, the outer shape of the bonding pad 38 is the square shape in which each of the four sides extends in the X direction or the Y direction. In the plane perpendicular to the stacking direction, the bonding pad 38 includes the region continuously disposed around the first insulating portion 36. That is, when viewed from the Z direction, the first insulating portion 36 is not connected to the first interlayer insulating film 35, and the bonding pad 38 is disposed between the first insulating portion 36 and the first interlayer insulating film 35. In the first example, the first insulating portion 36 is disposed in the island shape at the center of the bonding pad 38, and the shape of the first insulating portion 36 as viewed from the Z direction is the circular shape. A diameter d1 of the first insulating portion 36 is smaller than the width W1 of the bonding pad 38 in the X direction. By setting the shape of the bonding pad 38 to the shape of the bonding pad of the first example, the recess amount of the recessed portion can be reduced.

<6.2 Second Example>

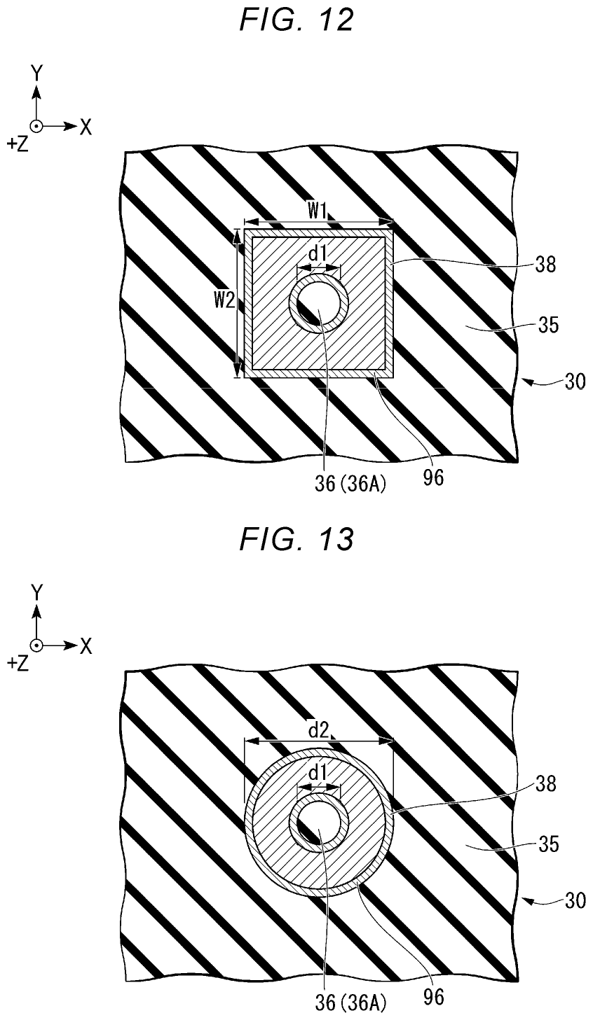

FIG. 13 is a cross-sectional view showing the shape of the bonding pad 38 according to a second example. FIG. 13 shows the bonding pad 38 on the plane perpendicular to the stacking direction when the stacking direction is the direction in which the circuit chip (first layer) 2 and the array chip (second layer) 3 are stacked. In the second example, the outer shape of the bonding pad 38 viewed from the Z direction is the circular shape. In the plane perpendicular to the stacking direction, the bonding pad 38 includes the region continuously disposed around the first insulating portion 36. In the second example, the first insulating portion 36 is disposed in the island shape at the center of the bonding pad 38, and the shape of the first insulating portion 36 as viewed from the Z direction is the circular shape. The diameter d1 of the first insulating portion 36 is smaller than a width d2 of the bonding pad 38 in the X direction. By setting the shape of the bonding pad 38 to the shape of the bonding pad of the second example, the recess amount of the recessed portion can be reduced.

<6.3 Third Example>

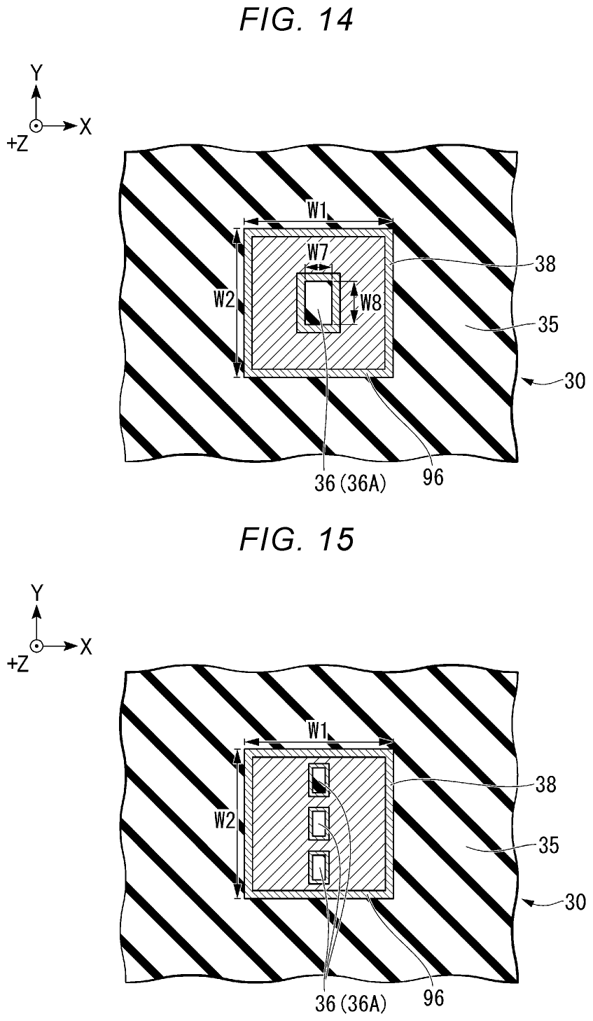

FIG. 14 is a cross-sectional view showing the shape of the bonding pad 38 according to a third example. FIG. 14 shows the bonding pad 38 on the plane perpendicular to the stacking direction when the stacking direction is the direction in which the circuit chip (first layer) 2 and the array chip (second layer) 3 are stacked. In the third example, the outer shape of the bonding pad 38 viewed from the Z direction is the quadrilateral shape. Specifically, the outer shape of the bonding pad 38 is the square shape in which each of the four sides extends in the X direction or the Y direction. In the plane perpendicular to the stacking direction, the bonding pad 38 includes the region continuously disposed around the first insulating portion 36. That is, when viewed from the Z direction, the first insulating portion 36 is not connected to the first interlayer insulating film 35, and the bonding pad 38 is disposed between the first insulating portion 36 and the first interlayer insulating film 35. In the third example, the first insulating portion 36 is disposed in the island shape at the center of the bonding pad 38, and the shape of the first insulating portion 36 as viewed from the Z direction is a rectangular shape in which each of the four sides extends in the X direction or the Y direction. A width W7 of the first insulating portion 36 in the X direction is smaller than the width W1 of the bonding pad 38 in the X direction. A width W8 of the first insulating portion 36 in the Y direction is smaller than the width W2 of the bonding pad 38 in the Y direction. By setting the shape of the bonding pad 38 to the shape of the bonding pad of the third example, the recess amount of the recessed portion can be reduced.

<6.4 Fourth Example>

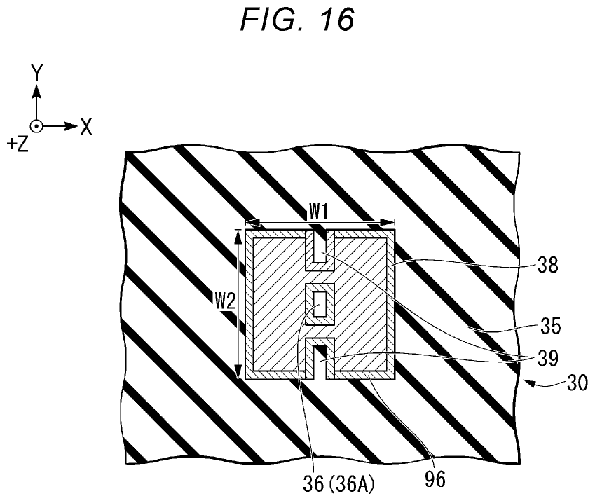

FIG. 15 is a cross-sectional view showing the shape of the bonding pad 38 according to a fourth example. FIG. 15 shows the bonding pad 38 on the plane perpendicular to the stacking direction when the stacking direction is the direction in which the circuit chip (first layer) 2 and the array chip (second layer) 3 are stacked. In the fourth example, the outer shape of the bonding pad 38 viewed from the Z direction is the quadrilateral shape. Specifically, the outer shape of the bonding pad 38 is the square shape in which each of the four sides extends in the X direction or the Y direction. In the plane perpendicular to the stacking direction, the bonding pad 38 includes the region continuously disposed around the first insulating portion 36. That is, when viewed from the Z direction, the first insulating portion 36 is not connected to the first interlayer insulating film 35, and the bonding pad 38 is disposed between the first insulating portion 36 and the first interlayer insulating film 35. In the fourth example, the plurality of first insulating portions 36 are arranged in the island shape at the center of the bonding pad 38. The plurality of first insulting portions 36 are provided evenly separated in the Y direction. By setting the shape of the bonding pad 38 to the shape of the bonding pad of the fourth example, the recess amount of the recessed portion can be reduced.

<6.5 Fifth Example>

FIG. 16 is a cross-sectional view showing the shape of the bonding pad 38 according to a fifth example. FIG. 16 shows the bonding pad 38 on the plane perpendicular to the stacking direction when the stacking direction is the direction in which the circuit chip (first layer) 2 and the array chip (second layer) 3 are stacked. In the plane perpendicular to the stacking direction, the bonding pad 38 includes the region continuously disposed around the first insulating portion 36. In the fifth example, the first insulating portion 36 is disposed in the island shape at the center of the bonding pad 38. That is, when viewed from the Z direction, the first insulating portion 36 is not connected to the first interlayer insulating film 35, and the bonding pad 38 is disposed between the first insulating portion 36 and the first interlayer insulating film 35. In addition, a protruding insulating portion 39 that is continuously connected to the first interlayer insulating film 35 and protrudes toward a bonding pad 38 side is provided. A shape of the protruding insulating portion 39 is the quadrilateral shape here, but the shape of the protruding insulating portion 39 is not particularly limited.

In the fifth example, the first insulating portion 36 and the two protruding insulating portions 39 are provided evenly separated in the Y direction. By setting the shape of the bonding pad 38 to the shape of the bonding pad of the fifth example, the recess amount of the recessed portion can be reduced.

The embodiment, the modifications, and some examples have been described above. However, the embodiment, the modifications, and the examples are not limited to those described above. In all the above description, the shapes of the bonding pad 38 and the bonding pad 48 may be reversed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first layer including a plurality of first pads; and
a second layer including a plurality of second pads;
wherein the plurality of first pads are bonded to the plurality of second pads, respectively, wherein
at least one of the first pads or the second pads continuously surrounds an insulating portion.

2. The semiconductor device according to claim 1, wherein
both of the first layer and the second layer include the insulating portion, and
both of the first pads and second pads continuously surround the insulating portion.

3. The semiconductor device according to claim 1, wherein
the insulating portion is formed as an island shape.

4. The semiconductor device according to claim 3, wherein
the insulating portion is formed as a circular shape.

5. The semiconductor device according to claim 3, wherein
the insulating portion is formed as a quadrilateral shape.

6. The semiconductor device according to claim 1, wherein
the first layer includes:
a first support substrate; and
a first stacked body provided between the first support substrate and the second layer, and including a first wiring connected to at least one of the first pads are, and a first interlayer insulating film, and
the second layer includes:
a second support substrate; and
a second stacked body provided between the first stacked body and the second support substrate, and including a second wiring connected to at least one of the second pads, and a second interlayer insulating film.

7. A substrate, comprising:
a plurality of pads; and
one or more insulating portions made of an insulator, wherein
at least one of the pads continuously surrounds one of the one or more insulating portions.

8. The substrate according to claim 7, wherein
the insulating portion is formed as an island shape.

9. The substrate according to claim 7, wherein
the insulating portion is formed as a circular shape.

10. The substrate according to claim 7, wherein
the insulating portion is formed as a quadrilateral shape.

11. The substrate according to claim 7, further comprising:
a first support substrate; and
a first stacked body provided on the first support substrate, and including a first wiring connected to the pads, and a first interlayer insulating film.

12. The semiconductor device according to claim 6, wherein each of the first pads and each of the second pads has a first portion disposed closer to a corresponding one of the first and second support substrates, and a second portion disposed less closer to the corresponding one of the first and second support substrates.

13. The semiconductor device according to claim 12, wherein the first portion has a first width and the second portion has a second width, the second width wider than the first width.

14. A method, comprising:
providing a first support substrate;
forming a first stacked body on the first support substrate, wherein the first stacked body includes a plurality of first pads, a first wiring connected to the first pads, and a first interlayer insulating film; and
providing a second support substrate;
forming a second stacked body on the second support substrate, wherein the second stacked body includes a plurality of second pads, a second wiring connected to the second pads, and a second interlayer insulating film; and
coupling the first stacked body to the second stacked body through the first pads and the second pads;
wherein at least one of the first pads or the second pads continuously surrounds an insulating portion.
